(19) United States
(12) Patent Application Publication
(10) Pub. No.: US 2025/0240906 A1
(43) Pub. Date: Jul. 24, 2025

(54) FASTENERS FOR FASTENING CIRCUIT CARDS

(71) Applicant: Steering Solutions IP Holding Corporation, Saginaw, MI (US)

(72) Inventors: Joshua Dornseifer, Saginaw, MI (US); Dustin N. Pogoreski, Saginaw, MI (US); Zachary Weiss, Bay City, MI (US)

(21) Appl. No.: 18/416,062

(22) Filed: Jan. 18, 2024

(51) Int. Cl. H05K 7/14; F16B 5/02

(52) U.S. Cl. CPC H05K 7/1407; F16B 5/02

(57) ABSTRACT

A fastener for fastening circuit card assemblies to metal castings, the fastener including: a head having a first radius; a pin having a second radius smaller than the first radius, the pin extending from the head along a longitudinal axis, the pin including an outer surface circumferentially surrounding the longitudinal axis and a surface feature extending on the outer surface from the head toward a tip of the pin, the surface feature including: a helical knurl having a plurality of knurls extending from the head to the tip of the pin, the plurality of knurls forming a helix wherein each of the plurality of knurls at least partially circumferentially surrounds the longitudinal axis.

### TECHNICAL FIELD

The present specification generally relates to fasteners and, more specifically, fasteners for fastening circuit card assemblies to metal castings.

### BACKGROUND

Screws are used in various manufacturing processes to attach one component to another. Manufacturing using screws requires controlling of torque values when fastening the components together. Controlling torque can be difficult to replicate and increase the time required for manufacture. Additionally, overtightening of the screws can result in damage to the components being attached together. Accordingly, a need exists for alternative fasteners for attaching two components together.

### SUMMARY

In one embodiment, a fastener for fastening circuit card assemblies to metal castings, the fastener includes: a head having a first radius; a pin having a second radius smaller than the first radius, the pin extending from the head along a longitudinal axis, the pin including an outer surface circumferentially surrounding the longitudinal axis and a surface feature extending on the outer surface from the head toward a tip of the pin, the surface feature including: a helical knurl having a plurality of knurls extending from the head to the tip of the pin, the plurality of knurls forming a helix wherein each of the plurality of knurls at least partially circumferentially surrounds the longitudinal axis.

In another embodiment, a fastener for fastening circuit card assemblies to metal castings, the fastener includes: a head having a first radius; a pin having a second radius smaller than the first radius, the pin extending from the head along a longitudinal axis, the pin including an outer surface circumferentially surrounding the longitudinal axis and a surface feature extending on the outer surface from the head toward a tip of the pin, the surface feature including: a plurality of barbs, each of the plurality of barbs circumferentially surrounds the longitudinal axis, and the plurality of barbs are spaced apart along the longitudinal axis.

In yet another embodiment, a circuit card assembly includes: a circuit card including a first opening; a metal casting including a second opening; and a fastener including a head and a pin extending from the head, the pin including an outer surface circumferentially surrounding the longitudinal axis and a surface feature extending on the outer surface from the head toward a tip of the pin configured to couple the circuit card to the metal casting when the pin is positioned in the first opening and the second opening, and the fastener completes a ground path between the circuit card and the metal casting when positioned in the first opening and the second opening.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 depicts a cross-sectional side view of a fastener being inserted into a circuit card assembly and a metal casting, according to one or more embodiments shown and described herein;

FIG. 2 depicts an example fastener for attaching a circuit card assembly to a metal casting, according to one or more embodiments shown and described herein; and

FIG. 3 depicts another example fastener for attaching a circuit card assembly to a metal casting, according to one or more embodiments shown and described herein.

### DETAILED DESCRIPTION

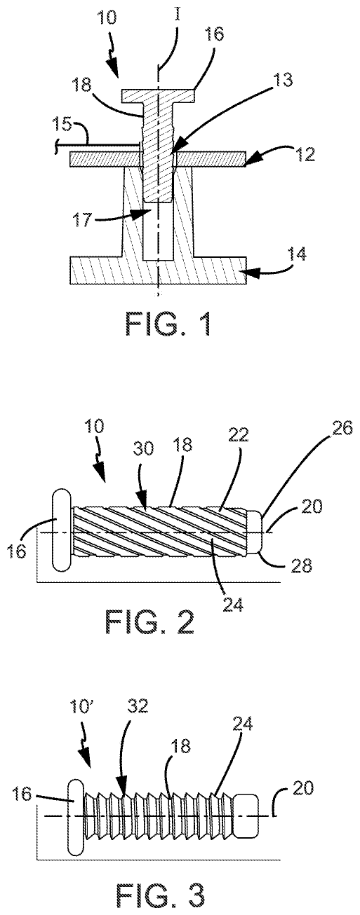

Referring initially to FIG. 1, a circuit card assembly 12 being fastened to a metal casting 14 is depicted. The circuit card assembly 12 is fastened to the metal casting 14 by a fastener 10 through a press-fit engagement. The circuit card assembly 12 includes a first attachment opening 13 and a ground path 15 extending from electronic components (e.g., capacitors, transistors, inductors, etc.) on the circuit card assembly 12 to the first attachment opening 13 or in proximity to the first attachment opening 13 such that a head 16 of the fastener 10 contacts the ground path 15 when the fastener 10 is inserted into the first attachment opening 13. It is also contemplated and possible that the ground path 15 extends into the opening 13 such that a pin 18 of the fastener 10 contacts the ground path 15. The metal casting 14 includes a second attachment opening 17 for receiving the fastener 10. Each of the first attachment opening 13 and the second attachment opening 17 may have an opening radius that is less than a second radius of a pin 18 of the fastener 10. The smaller radius of the attachment openings 13, 17 allows for the pin 18 to engage the openings 13, 17 in a press-fit engagement. The metal casting 14 may be any component made of metal, such as a heat sink, an electric motor housing, or the like. The metal may be an aluminum, a steel, or the like that can be used to ground the circuit card assembly 12.

The fastener 10 extends into the first attachment opening 13 of the circuit card assembly 12 and the second attachment opening 17 of the metal casting 14 to couple the circuit card assembly 12 to the metal casting 14, where the fastener 10 completes the ground path 15 between the circuit card assembly 12 and the metal casting 14, thereby grounding the circuit card assembly 12. As shown in phantom, the fastener 10 may be inserted into the circuit card assembly 12 and the metal casting 14 along an insertion axis I that extends through a center of the first attachment opening 13 and the second attachment opening 17 and along a length of the pin 18.

Referring now to FIG. 2, a first embodiment of the fastener 10 of FIG. 1 is depicted. The fastener 10 includes the head 16 and the pin 18 extending from the head 16 along a longitudinal axis 20. The head 16 has a first radius and the pin 18 has a second radius that is less than the first radius. The pin 18 includes an outer surface 22 circumferentially surrounding the longitudinal axis 20 and a surface feature 24 extending on the outer surface 22 from the head 16 toward a tip 26 of the pin 18. The surface feature 24 may be at least one of a plurality of barbs 32, a helical knurl 30, and a plurality of threads. The depicted fastener 10 of FIG. 2 includes the helical knurl 30. The helical knurl 30 includes a plurality of knurls extending from the head 16 to the tip 26 of the pin 18, where the plurality of knurls form a helix, and each of the plurality of knurls at least partially circumferentially surrounds the longitudinal axis 20. The helical knurl 30 may include a height or radius that extends past the radius of the pin 18, where the radius of the helical knurl 30 extending past the pin 18 may be 0.15 mm. When the fastener 10 is inserted into the attachment openings, the helical knurl 30 may rotate the fastener 10 as the fastener 10 moves into the attachment openings. The helical knurl 30 similarly causes the fastener 10 to rotate when the fastener 10 is being removed from the attachment openings. However, a tool, such as a claw head hammer, provides a normal force against the head 16 of the fastener 10 during removal, thereby resisting rotation of the fastener 10 and increasing the force required for removing the fastener 10 when compared to insertion. The helical knurl 30 may include any operable number of knurls, such as 1, 20, between 1 and 20, or more than 20 knurls. Each knurl may be disposed at an angle relative to the longitudinal axis 20 when viewed in a side view. The angle may be between 10° and 80°, more specifically, between 25° and 40° including endpoints.

The fastener 10 may include a chamfer 28 at the tip 26 of the pin 18 that has an angle between 25° and 40° relative to the longitudinal axis 20 or a fillet. The fastener 10 may further include a length of the pin 18 that does not include the surface feature 24 positioned between the surface feature 24 and a tip 26 of the pin 18, where the length of the pin 18 without the surface feature 24 extends from the surface feature 24 to the chamfer 28. The length of the portion of the pin 18 without the surface feature 24 may be one third (⅓) of a diameter of the length of the portion of the pin 18 without the surface feature 24. In other words, the ratio of the length to the diameter of the portion of the pin 18 without the surface feature 24 is ⅓. The opening 17 in the metal casting 14 may be sized to have the same or slightly greater radius as the length of the portion of the pin 18 without the surface feature 24. For example, the opening 17 may have a radius up to 0.03 mm greater than a radius of the length of the portion of the pin 18 without the surface feature 24. The fastener 10 may include a zinc coating (or other coating that permits grounding) for preventing corrosion.

Now referring to FIG. 3, another embodiment of the fastener 10′ is depicted. The fastener 10′ may include each of the features described above with reference to FIG. 2, except for the surface feature 24. Accordingly, like features will not be described again for brevity. The surface feature 24 of the fastener 10′ may be a plurality of barbs 32, where each of the plurality of barbs 32 circumferentially surrounds the longitudinal axis 20 and the plurality of barbs 32 are spaced apart along the longitudinal axis 20. The plurality of barbs 32 are arranged sequentially along the longitudinal axis 20. The plurality of barbs 32 may include any operable numbers of barbs, including 1, 20, or any number in between and, more specifically, 12 barbs. The barbs 32 may each have a uniform thickness (e.g., distance along the longitudinal axis 20) and a uniform spacing between barbs along the longitudinal axis 20. The barbs 32 may have a radius that is 0.15 mm greater than a radius of the pin 18. The barbs 32 may be angled to be at least 10 degrees from an axis perpendicular to the axis 20. The barbs 32 may be angled to permit insertion of the pin 18 into the opening 17.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A fastener for fastening circuit card assemblies to metal castings, the fastener comprising:
a head having a first radius;
a pin having a second radius smaller than the first radius, the pin extending from the head along a longitudinal axis, the pin comprising an outer surface circumferentially surrounding the longitudinal axis and a surface feature extending on the outer surface from the head toward a tip of the pin, the surface feature comprising:
a helical knurl having a plurality of knurls extending from the head toward the tip of the pin, the plurality of knurls forming a helix wherein each of the plurality of knurls at least partially circumferentially surrounds the longitudinal axis.

2. The fastener of claim 1, further comprising a chamfer at the tip of the pin that has an angle between 25° and 40° relative to the longitudinal axis.

3. The fastener of claim 1, further comprising a length of the pin that does not include the surface feature positioned between the surface feature and the tip of the pin.

4. The fastener of claim 1, wherein a length of the surface feature is greater than a length of the portion of the pin that does not include the surface feature.

5. The fastener of claim 1, wherein the fastener is formed of a steel with a zinc coating.

6. The fastener of claim 1, wherein the plurality of knurls comprises at least 10 knurls.

7. The fastener of claim 1, wherein at least one of the plurality of knurls is disposed at an angle relative to the longitudinal axis, and the angle is between 25° and 40°.

8. A fastener for fastening circuit card assemblies to metal castings, the fastener comprising:
a head having a first radius;
a pin having a second radius smaller than the first radius, the pin extending from the head along a longitudinal axis, the pin comprising an outer surface circumferentially surrounding the longitudinal axis and a surface feature extending on the outer surface from the head toward a tip of the pin, the surface feature comprising:
a plurality of barbs, each of the plurality of barbs circumferentially surrounds the longitudinal axis, and the plurality of barbs are spaced apart along the longitudinal axis.

9. The fastener of claim 8, wherein the plurality of barbs are arranged sequentially along the longitudinal axis.

10. The fastener of claim 8, further comprising a chamfer at the tip of the pin that has an angle between 25° and 40° relative to the longitudinal axis.

11. The fastener of claim 8, further comprising a length of the portion of the pin that does not include the surface feature positioned between the surface feature and the tip of the pin.

12. The fastener of claim 8, wherein a length of the surface feature is greater than a length of the portion of the pin that does not include the surface feature.

13. The fastener of claim 8, wherein the fastener is formed of a steel with a zinc coating.

14. The fastener of claim 8, wherein the plurality of barbs comprises at least 10 barbs.

15. The fastener of claim 8, wherein the plurality of barbs are disposed at an angle relative to the longitudinal axis, and the angle is between 25° and 40°.

16. A circuit card assembly comprising:
a circuit card comprising a first opening;
a metal casting comprising a second opening; and
a fastener comprising a head and a pin extending from the head, the pin comprising an outer surface circumferentially surrounding the longitudinal axis and a surface feature extending on the outer surface from the head toward a tip of the pin configured to couple the circuit card to the metal casting when the pin is positioned in the first opening and the second opening, and the fastener completes a ground path between the circuit card and the metal casting when positioned in the first opening and the second opening.

17. The circuit card assembly of claim 16, wherein the surface feature comprises:
a helical knurl having a plurality of knurls extending from the head toward the tip of the pin, the plurality of knurls forming a helix wherein each of the plurality of knurls at least partially circumferentially surrounds the longitudinal axis.

18. The circuit card assembly of claim 17, wherein the plurality of knurls comprises at least 10 knurls.

19. The circuit card assembly of claim 17, wherein the plurality of knurls are disposed at an angle relative to the longitudinal axis, and the angle is between 25° and 40°.

20. The circuit card assembly of claim 16, wherein the surface feature comprises:
a plurality of barbs, each of the plurality of barbs circumferentially surrounds the longitudinal axis, and the plurality of barbs are spaced apart along the longitudinal axis.
